(19) United States
(12) Patent Application Publication
(10) Pub. No.: US 2014/0192597 A1
(43) Pub. Date: Jul. 10, 2014

(54) CIRCUIT FOR CONTROLLING EEPROM CELL

(71) Applicant: Electronics and Telecommunications Research Institute, Daejeon (KR)

(72) Inventor: Jin-Yeong KANG, Daejeon (KR)

(21) Appl. No.: 13/911,310

(22) Filed: Jun. 6, 2013

(30) Foreign Application Priority Data
Jan. 4, 2013 (KR) 10-2013-0001192

(51) Int. Cl. G11C 16/24; G11C 16/08

(52) U.S. Cl. CPC G11C 16/24; G11C 16/08
USPC 365/185.17

(57) ABSTRACT

An EEPROM cell control circuit is provided which includes a signal input circuit configured to receive control signals for controlling an EEPROM cell from an external device; a bit line control circuit configured to provide a positive voltage and a negative voltage to two bit lines connected with the EEPROM cell in response to the control signals; and a word line control circuit configured to control a sense gate line in response to the control signals at a sense operation and to apply a positive voltage and a negative voltage to a word line.

### CROSS-REFERENCE TO RELATED APPLICATIONS

A claim for priority under 35 U.S.C. §119 is made to Korean Patent Application No. 10-2013-0001192 filed Jan. 4, 2013, in the Korean Intellectual Property Office, the entire contents of which are hereby incorporated by reference.

### BACKGROUND

The inventive concepts described herein relate to a semiconductor memory, and more particularly, relate to a control circuit capable of controlling an EEPROM cell formed of a tunneling oxide film having a thin thickness.

EEPROM may be a kind of programmable read only memory (PROM), and may be implemented to overcome such a disadvantage of an erasable programmable read only memory (EPROM) that contents stored therein are erased by exposing it to strong ultraviolet light source. Data stored in the EEPROM may be erased by forcing an electric signal to a pin of a chip.

As a nonvolatile memory device, such an EEPROM may be applied to a system on chip, an RFID (Radio Frequency Identification) tag, and so on. The EEPROM may have various storage capacities ranging from dozen of bytes to several gigabytes according to the use. In the event that the EEPROM is used for the RFID, a superior adhesive strength may be required. For this reason, there may be required high-density and small-sized EEPROMs.

A tunneling insulation film (e.g., a tunneling oxide film) of the EEPROM may be formed to be thicker than about 70 angstroms. Thus, there need be reduced a thickness of the tunneling insulation film for a high-density and small-sized EEPROM. Also, there need be required a control circuit for enabling tunneling oxide films to be formed by the same thickness.

### SUMMARY

One aspect of embodiments of the inventive concept is directed to provide an EEPROM cell control circuit which comprises a signal input circuit configured to receive control signals for controlling an EEPROM cell from an external device; a bit line control circuit configured to provide a positive voltage and a negative voltage to two bit lines connected with the EEPROM cell in response to the control signals; and a word line control circuit configured to control a sense gate line in response to the control signals at a sense operation and to apply a positive voltage and a negative voltage to a word line.

In example embodiments, the input circuit comprises a first inverter configured to select either program and erase operations or standby and read operations; a second inverter configured to receive a program/erase mode control signal for controlling a program mode and an erase mode; and a third inverter configured to receive a word line selection signal for word line selection.

In example embodiments, the bit line control circuit comprises a first AND gate configured to receive control signals for applying a negative voltage to a first bit line of the two bit lines; a first voltage level converter connected with the first AND gate and to apply a negative voltage to the first bit line; a first NAND gate configured to receive control signals for applying a positive voltage to a second bit line of the two bit lines; and a second voltage level converter connected with the first NAND gate and to apply a positive voltage to the second bit line.

In example embodiments, each of the first and second voltage level converters comprises an input unit configured to receive a signal; voltage level conversion units connected to have a three-stage structure and to convert a voltage of the input signal based on a power supply voltage, a ground voltage, a high output voltage, a low output voltage, and an intermediate voltage; an output unit configured to output a signal the voltage of which is converted by the voltage level conversion units; and an operating voltage stabilizer configured to secure a normal function operation although a difference between operating voltages of elements in a voltage level conversion unit, located at a first stage, from among the voltage level conversion units is generated and to suppress power consumption.

In example embodiments, the operating voltage stabilizer includes two NMOS transistors connected with the intermediate voltage.

In example embodiments, the word line control circuit comprises a second NAND gate configured to receive a word line selection signal and a control signal for applying different voltages to two sense gate lines of the EEPROM cell at a read operation; and a first inverter circuit connected with the second NAND gate and configured to apply an operating voltage for the read operation to the two sense gate lines of the EEPROM cell.

In example embodiments, the word line control circuit comprises a second inverter circuit configured to receive a word line selection signal and a control signal for generating a voltage applied to a read voltage line at a read operation and to apply a read voltage to the read voltage line.

In example embodiments, the EEPROM cell control circuit further comprises a CMOS logic circuit configured to receive a word line selection signal and a control signal for generation of a positive voltage and a negative voltage applied to the word line; a third voltage level converter connected with the CMOS logic circuit and to generate a positive voltage applied to the word line; a first transfer gate configured to transfer an output of the third voltage level converter to the word line; a fourth voltage level converter connected with the CMOS logic circuit and to generate a negative voltage applied to the word line; and a second transfer gate configured to transfer an output of the fourth voltage level converter to the word line.

In example embodiments, a bias condition between drains and wells of the first and second transfer gates are at a reverse bias state such that a signal is not transferred between the first and second transfer gates.

In example embodiments, the first transfer gate generates a positive voltage, a zero voltage, and high-impedance, and the second transfer gate generates a negative voltage and high-impedance.

In example embodiments, the CMOS logic circuit comprises second and third NAND gates configured to receive a word line selection signal and a control signal for generation of a positive voltage of the third voltage level converter; a first NOR gate configured to perform a NOR operation on outputs of the second and third NAND gates to output a result of the NOR operation to the third voltage level converter; fourth and fifth NAND gates configured to receive a word line selection signal and a control signal for generation of a negative voltage of the fourth voltage level converter; and a second NOR gate configured to perform a NOR operation on outputs of the fourth and fifth NAND gates to output a result of the NOR operation to the fourth voltage level converter.

In example embodiments, each of the third and fourth voltage level converters comprises an input unit configured to receive a signal; voltage level conversion units connected to have a three-stage structure and to convert a voltage of the input signal based on a power supply voltage, a ground voltage, a high output voltage, a low output voltage, and an intermediate voltage; an output unit configured to output a signal the voltage of which is converted by the voltage level conversion units; and an operating voltage stabilizer configured to secure a normal function operation although a difference between operating voltages of elements in a voltage level conversion unit, located at a first stage, from among the voltage level conversion units is generated and to suppress power consumption.

In example embodiments, the operating voltage stabilizer includes two NMOS transistors connected with the intermediate voltage.

### BRIEF DESCRIPTION OF THE FIGURES

The above and other objects and features will become apparent from the following description with reference to the following figures, wherein like reference numerals refer to like parts throughout the various figures unless otherwise specified, and wherein

FIG. 1 is a diagram schematically illustrating an EEPROM cell control circuit according to an embodiment of the inventive concept.

FIG. 2 is a circuit diagram schematically illustrating a voltage level converter according to an embodiment of the inventive concept.

FIG. 3 is a diagram schematically illustrating functional transfer gates according to an embodiment of the inventive concept.

### DETAILED DESCRIPTION

Embodiments will be described in detail with reference to the accompanying drawings. The inventive concept, however, may be embodied in various different forms, and should not be construed as being limited only to the illustrated embodiments. Rather, these embodiments are provided as examples so that this disclosure will be thorough and complete, and will fully convey the concept of the inventive concept to those skilled in the art. Accordingly, known processes, elements, and techniques are not described with respect to some of the embodiments of the inventive concept. Unless otherwise noted, like reference numerals denote like elements throughout the attached drawings and written description, and thus descriptions will not be repeated. In the drawings, the sizes and relative sizes of layers and regions may be exaggerated for clarity.

It will be understood that, although the terms “first”, “second”, “third”, etc., may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the inventive concept.

Spatially relative terms, such as “beneath”, “below”, “lower”, “under”, “above”, “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” or “under” other elements or features would then be oriented “above” the other elements or features. Thus, the exemplary terms “below” and “under” can encompass both an orientation of above and below. The device may be otherwise oriented (rotated 90 degrees or at other orientations) and the spatially relative descriptors used herein interpreted accordingly. In addition, it will also be understood that when a layer is referred to as being “between” two layers, it can be the only layer between the two layers, or one or more intervening layers may also be present.

The terminology used herein is for the purpose of describing particular embodiments only and is not intended to be limiting of the inventive concept. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof. As used herein, the term “and/or” includes any and all combinations of one or more of the associated listed items. Also, the term “exemplary” is intended to refer to an example or illustration.

It will be understood that when an element or layer is referred to as being “on”, “connected to”, “coupled to”, or “adjacent to” another element or layer, it can be directly on, connected, coupled, or adjacent to the other element or layer, or intervening elements or layers may be present. In contrast, when an element is referred to as being “directly on,” “directly connected to”, “directly coupled to”, or “immediately adjacent to” another element or layer, there are no intervening elements or layers present.

Unless otherwise defined, all terms (including technical and scientific terms) used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art and/or the present specification and will not be interpreted in an idealized or overly formal sense unless expressly so defined herein.

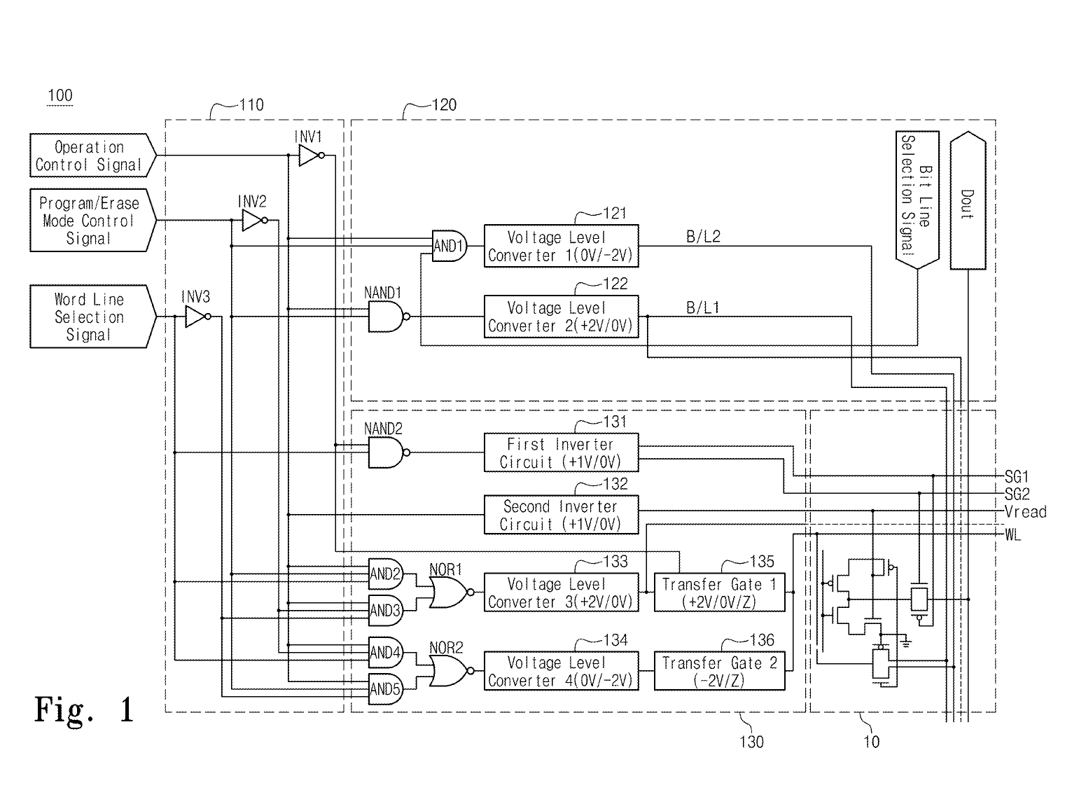

FIG. 1 is a diagram schematically illustrating an EEPROM cell control circuit according to an embodiment of the inventive concept.

Referring to FIG. 1, an EEPROM cell control circuit 100 may output a control signal to an EEPROM cell 10.

The EEPROM cell control circuit 100 may include a signal input circuit 110, a bit line control circuit 120, and a word line control circuit 130.

The signal input circuit 110 may receive an operation control signal, a program/erase mode control signal, and a word line selection signal.

The signal input circuit 110 may receive signals for operations of the bit line control circuit 120 and the word line control circuit 130, and may output the input signals to the bit line control circuit 120 and the word line control circuit 130.

The signal input circuit 110 may receive an operation control signal PgmErs(1)/RdSb(0) which has a logical ‘1’ at a program or erase operation and a logical ‘0’ at a read or standby operation. The signal input circuit 110 may output the input operation control signal to the bit line control circuit 120 and the word line control circuit 130.

The signal input circuit 110 may receive a program/erase mode control signal PgmMode(1)/ErsMode(0) which has a logical ‘1’ at a program mode and a logical ‘0’ at an erase mode. The signal input circuit 110 may output the input operation control signal to the bit line control circuit 120 and the word line control circuit 130.

The signal input circuit 110 may receive a word line selection signal WLSel(1)/notWLSel(0) which has a logical ‘1’ at word line selection and a logical ‘0’ at word line non-selection. The signal input circuit 110 may output the input operation control signal to the bit line control circuit 120 and the word line control circuit 130.

The signal input circuit 110 may include a first inverter INV1 for inverting an operation control signal, a second inverter INV2 for inverting a program/erase mode control signal, and a third inverter INV3 for inverting a word line selection signal.

The first inverter INV1 may invert the operation control signal to output it to the word line control circuit 130.

The second inverter INV2 may invert the program/erase mode control signal to output it to the bit line control circuit 120 and the word line control circuit 130.

The third inverter INV3 may invert the word line selection signal to output it to the word line control circuit 130.

The bit line control circuit 120 may receive the operation control signal and the program/erase mode control signal. The bit line control circuit 120 may receive a bit line selection signal BLSel(1)/notBLSel(0) having a logical ‘1’ at bit line selection and a logical ‘0’ at bit line non-selection.

The bit line control circuit 120 may provide two bit lines connected with the EEPROM cell 10 with a bit line voltage in response to the operation control signal, a program/erase mode control signal, and a bit line selection signal. Bit line voltages generated from the bit line control circuit 120 may be divided into a positive voltage (0V to +2V) and a negative voltage (−2V to 0V).

The bit line control circuit 120 may include a first AND gate AND1, a first NAND gate NAND1, a first voltage level converter 121, and a second voltage level converter 122.

The first AND gate AND may perform an AND operation on the operation control signal, the program/erase control mode signal, and the bit line selection signal, An output of the first AND gate AND1 may be transferred to the first voltage level converter 121.

The first voltage level converter 121 may generate a bit line voltage (e.g., about −2V to 0V) in response to the output of the first AND gate AND1. The first voltage level converter 121 may output the bit line voltage (e.g., about −2V to 0V) to a second bit line BL2 of the EEPROM cell 10.

The first NAND gate NAND1 may perform a NAND operation on the operation control signal and the program/erase control mode signal. An output of the first NAND gate NAND1 may be transferred to the second voltage level converter 122.

The second voltage level converter 122 may generate a bit line voltage (e.g., about 0V to +2V) in response to the output of the first NAND gate NAND1. The second voltage level converter 122 may output the bit line voltage (e.g., about 0V to +2V) to a first bit line BL1 of the EEPROM cell 10.

As the first voltage level converter 121 and the second voltage level converter 122 are controlled by the first AND gate AND1 and the first NAND gate NAND1, one of the he first voltage level converter 121 and the second voltage level converter 122 may operate. Thus, the bit line control circuit 120 may provide a bit line voltage to one of the first bit line BL1 and the second bit line BL2.

A symmetric voltage of a negative voltage (e.g., −2V) and a positive voltage (e.g., +2V) output from the first voltage level converter 121 and the second voltage level converter 122 may be applied to a bit line. Tunneling of the EEPROM cell 10 may be generated at a positive voltage (e.g., +2V) or 4V being two times higher than a negative voltage (e.g., −2V).

The word line control circuit 130 may receive the operation control signal, the program/erase mode control signal, and the word line selection signal. Also, the word line control circuit 130 may receive an inverted operation control signal, an inverted program/erase mode control signal, and an inverted word line selection signal.

The word line control circuit 130 may control sense gate lines for controlling an output of data at a sensing operation in response to the operation control signal and the inverted operation control signal. Also, the word line control circuit 130 may apply a word line voltage to a word line in response to the operation control signal, the program/erase mode control signal, the word line selection signal, the inverted operation control signal, the inverted program/erase mode control signal, and the inverted word line selection signal.

The word line control circuit 130 may include a second NAND gate NAND2, a first inverter circuit 131, a second inverter circuit 132, a second AND gate AND2, third AND gate AND3, fourth AND gate AND4, a fifth AND gate AND5, a first NOR gate NOR1, a second NOR gate NOR2, a third voltage level converter 133, a fourth voltage level converter 134, a first transfer gate 135, and second transfer gate 136.

The second NAND gate NAND2 may perform a NAND operation on an inverted operation control signal and a word line selection signal. An output of the second NAND gate NAND2 may be transferred to the first inverter circuit 131.

The first inverter circuit 131 may generate a voltage of about +1V or 0V in response to an output of the second NAND gate NAND2. The inverter circuit 131 may output the voltage of about +1 V or 0V to a first sense gate line SG1 and a second sense gate line SG2. For example, the first inverter circuit 131 may include two inverters connected in series each other. The first inverter circuit 131 may have an output buffer function, and an output of the first inverter circuit 131 may be transferred to a sense gate lines.

The first inverter circuit 131 may be connected to sense gate lines of the EEPROM cell 10. At a read operation, the first inverter circuit 131 may apply a voltage to the first sense gate line SG1 and the second sense gate line SG2 such that data Dout is output via a sense line. For example, at a read operation, the first inverter circuit 131 may apply a voltage of 0V to the first sense gate line SG1 connected with an NMOS transistor of the EEPROM cell 10 and a voltage of 1V to the second sense gate line SG2 connected with a PMOS transistor of the EEPROM cell 10. In this case, data Dout may be output via a sense line of the EEPROM cell 10.

The second inverter circuit 132 may receive the operation control signal. The second inverter circuit 132 may generate a voltage (e.g., about +1V or 0V) in response to the operation control signal. The second inverter circuit 132 may output the voltage (e.g., about +1V or 0V) to a read voltage line Vread. For example, the second inverter circuit 132 may include an inverter.

Herein, at program and erase operations, the second inverter circuit 132 may apply a voltage of 0V to the read voltage line Vread. Also, at a read operation, the second inverter circuit 132 may apply a voltage of 1V to the read voltage line Vread. The second inverter circuit 132 may float an inverter circuit in the EEPROM cell at operations excepting the read operation.

The second AND gate AND2 may perform an AND operation on the operation control signal, the program/erase mode control signal, and the word line selection signal. An output of the second AND gate AND2 may be transferred to the first NOR gate NOR1.

The third AND gate AND3 may perform an AND operation on the operation control signal, the inverted program/erase mode control signal, and the inverted word line selection signal. An output of the third AND gate AND3 may be transferred to the first NOR gate NOR1.

The first NOR gate NOR1 may perform a NOR operation on an output of the second AND gate AND2 and an output of the third AND gate AND3. An output of the first NOR gate NOR1 may be transferred to the third voltage level converter 133.

The third voltage level converter 133 may generate a voltage (e.g., about 0V to +2V) in response to an output of the first NOR gate NOR1. The third voltage level converter 133 may output the voltage (e.g., about 0V to +2V) to the first transfer gate 135.

The first transfer gate 135 may generate a voltage (e.g., +2V, 0V or high-impedance) in response to a first transfer gate control voltage output from the third voltage level converter 133. The first transfer gate 135 may output the generated voltage to a word line WL.

The first voltage level converter 121 may generate a bit line voltage (e.g., about −2V to 0V) in response to an output of the first AND gate AND1. The first voltage level converter 121 may output the bit line voltage (e.g., about −2V to 0V) to the second bit line BL2 of the EEPROM cell 10.

The fourth AND gate AND4 may perform an AND operation on the operation control signal, the inverted program/erase mode control signal, and the word line selection signal. An output of the fourth AND gate AND4 may be transferred to the second NOR gate NOR2.

The fifth AND gate AND5 may perform an AND operation on the operation control signal, the program/erase mode control signal, and the inverted word line selection signal. An output of the fifth AND gate AND5 may be transferred to the second NOR gate NOR2.

The second NOR gate NOR2 may perform a NOR operation on an output of the fourth AND gate AND4 and an output of the fifth AND gate AND5. An output of the first NOR gate NOR1 may be transferred to the fourth voltage level converter 134.

The second NOR gate NOR2 may perform a NOR operation on an output of the fourth AND gate AND4 and an output of the fifth AND gate AND5. An output of the second NOR gate NOR2 may be transferred to the fourth voltage level converter 134.

The fourth voltage level converter 134 may generate a voltage (e.g., about −2V to 0V) in response to an output of the second NOR gate NOR2. The fourth voltage level converter 134 may output a second transfer gate control voltage (about 0V to +2V) to the second transfer gate 136.

The second transfer gate 136 may generate a voltage (e.g., −2V or high-impedance) in response to the second transfer gate control voltage from the fourth voltage level converter 134. The second transfer gate 136 may output the generated voltage to the word line WL.

Outputs of the first transfer gate 135 and the second transfer gate 136 may be connected with the word line WL such that one of the outputs of the first transfer gate 135 and the second transfer gate 136 is provided to the word line WL. The first transfer gate 135 and the second transfer gate 136 may output a word line selection signal.

Below, an operation of the EEPROM cell control circuit 100 according to an embodiment of the inventive concept will be more fully described.

The EEPROM cell control circuit 100 may perform a program or erase operation in response to the operation control signal having a logical ‘1’ (e.g., 1V). Also, the EEPROM cell control circuit 100 may perform a read or standby operation in response to the operation control signal having a logical ‘0’ (e.g., 0V). Since being at a stabilized state, the read and standby operations may be the same operating state. At this time, the EEPROM cell control circuit 100 may not be affected by the word line selection signal and the bit line selection signal.

The EEPROM cell control circuit 100 may enter a program mode in response to the program/erase mode control signal having a logical ‘1’ (e.g., 1V). The EEPROM cell control circuit 100 may enter an erase mode in response to the program/erase mode control signal having a logical ‘0’ (e.g., 0V).

If the word line selection signal having a logical ‘1’ is applied to the EEPROM cell control circuit 100 entering the erase mode, data of a selected word line may be erased at the same time.

The EEPROM cell control circuit 100 may select a corresponding word line in response to an input of the word line selection signal having a logical ‘1’. The EEPROM cell control circuit 100 may not select a corresponding word line in response to an input of the word line selection signal having a logical ‘0’ (e.g., approximately 0V).

The EEPROM cell control circuit 100 may select a corresponding bit line in response to an input of the bit line selection signal having a logical ‘1’. The EEPROM cell control circuit 100 may not select a corresponding bit line in response to an input of the bit line selection signal having a logical ‘0’ (e.g., approximately 0V).

At a program operation, the EEPROM cell control circuit 100 may control such that data is programmed at an EEPROM cell corresponding to a selected bit line and an EEPROM cell corresponding to an unselected bit line is at a standby state. Also, the EEPROM cell control circuit 100 may apply about −2V to all unselected word lines and about 0V to all unselected bit lines.

At an erase operation, the EEPROM cell control circuit 100 may control such that EEPROM cells in a selected word line are simultaneously erased regardless of bit line selection. The EEPROM cell control circuit 100 may apply about −2V to a selected word line and about +2V to a selected bit line. The EEPROM cell control circuit 100 may apply about +2V to all unselected word lines and 0V to all unselected bit lines.

At a read operation, the EEPROM cell control circuit 100 may control such that data stored at EEPROM cells connected with bit lines corresponding to a selected word line is output to a latch buffer 20. At this time, the latch buffer 20 may latch an output value in response to a low-to-high transition of a latch enable signal Latch_En and output the latched data when its logical value is maintained with 1. At a standby operation, the EEPROM cell control circuit 100 may apply about +2V or −2V to a word line regardless of selection. However, the EEPROM cell control circuit 100 may apply about 0V to all selected bit lines.

An operation of an EEPROM cell may be divided into a program operation, an erase operation, a read operation, and a standby operation. There may be illustrated operations of an inverter circuit at a program operation, an erase operation, a read operation, and a standby operation. The following table 1 may show operating conditions of the EEPROM cell.

TABLE 1

| | | | | All | |
|---|---|---|---|---|---|
| | | | | stand | |
| | Pgm | Ers | Read | by | connection |
| PgmErsST(1)/ | 1 | 1 | 0 | 0 | W/L, B/L |
| RdSbST(0) | | | | | |
| WLSel(1)/notSel(0) | Sel(1)/ | Sel(1)/ | Sel(1)/ | Don't | W/L |
| | not(0) | not(0) | not(0) | care | |
| BLSet(1)/notSet(0) | Sel(1)/ | Don't care | Don't care | Don't | B/L |
| | not(0) | | | care | |
| PgmMode(1)/ | 1 | 0 | Don't care | Don't | W/L, B/L |
| ErsMode(0) | | | | care | |

The following table 2 may show voltages applied to selected and unselected cells at a program operation, an erase operation, a sense operation, and a standby operation.

TABLE 2

| Area | Lines | Standby | Erase | Write | Sensing |
|---|---|---|---|---|---|
| Sel. Cell | Word line | +2 V~−2 V | −2 V | 2 V | 0 V |
| | Bit line | 0 V | 2 V | −2 V | 0 V |
| | Sense gate | 0 V | 0 V | 0 V | +1.0 V |
| | line | | | | |
| | Sense line | High-Z | High-Z | High-Z | Data |
| | | | | | (V-reading) |
| Unsel. | Word line | −2 V~+2 V | 2 V | −2 V | 0 V |
| Cell | Bit line | 0 V | 2 V | −2 V | 0 V |
| | Sense gate | 0 V | 0 V | 0 V | 0 V |
| | line | | | | |
| | Sense line | High-Z | High-Z | High-Z | High-Z |
| Internal | Read | 0 V | 0 V | 0 V | +1.0 V |
| Inverter | voltage line | | | | |

That is, at a program operation, an erase operation, and a standby operation, one of about +2V (programming) and about +2V (erasing) may be applied to a word line. At a standby operation, a word line may be set to about +2V or −2V (don't care). A bit line may be set to +2V (erasing), −V (standby), and −2V (programming). Operations may be performed according to an order of standby, erase, standby, program, standby, and so on.

As described above, the EEPROM cell control circuit 100 may be a basic CMOS cell formed of an inverter, an AND gate, a NAND gate, an OR gate, a NOR gate, and an inverter (formed of two inverters connected in series and indicating an output and an opposite output). Herein, an inverter may have an output buffer function.

Since positive and negative symmetric voltages +2V and −2V are used, the EEPROM cell control circuit 100 may be used as a control circuit for controlling an EEPROM cell having one type of thin oxide film.

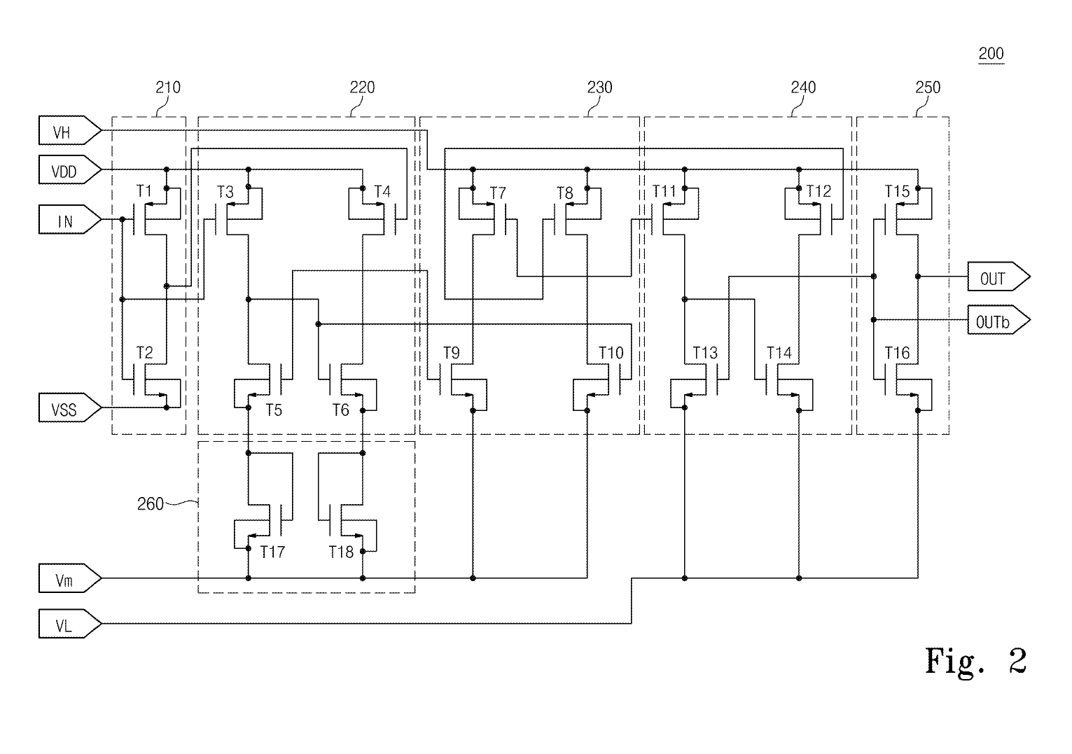

FIG. 2 is a circuit diagram schematically illustrating a voltage level converter according to an embodiment of the inventive concept.

Referring to FIG. 2, a voltage level converter 200 may correspond to each of first to fourth voltage level converters 121, 122, 133, and 134 in FIG. 1.

The voltage level converter 200 may have a function of a voltage conversion inverter which receives a CMOS input signal (e.g., 0V to 1V) to output a voltage (e.g., 0V to +2V or −2V to 0V) needed for a program/erase operation of an EEPROM array.

The voltage level converter 200 may include an input unit 210, a first voltage level conversion unit 220, a second voltage level conversion unit 230, a third voltage level conversion unit 240, an output unit 25, and an operating voltage stabilizer 260.

The input unit 210 may include a first transistor T1 and a second transistor T2. The first transistor T1 and the second transistor T2 may be connected in series between a power supply voltage VDD and a ground voltage VSS. An input voltage may be output to the first voltage level conversion unit 220 via connection between drains of the first transistor T1 and the second transistor T2 and connection between gates of the first transistor T1 and the second transistor T2.

The first voltage level conversion unit 220 may include a third transistor T3, a fourth transistor T4, a fifth transistor T5, and a sixth transistor T6.

The third transistor T3 and the fourth transistor T4 may be connected with the power supply voltage VDD, the fifth transistor T5 may be connected between the third transistor T3 and an operating voltage extension unit 260, and the sixth transistor T6 may be connected between the fourth transistor T4 and the operating voltage extension unit 260.

A gate of the third transistor T3 may be connected with gains of the first transistor T1 and the second transistor T2, and a gate of the fourth transistor T4 may be connected with connection between drains of the first transistor T1 and the second transistor T2.

A first voltage conversion signal may be output to the second voltage level conversion unit 230 via connection of the third transistor T3 and the fifth transistor T5 and connection of the fourth transistor T4 and the sixth transistor T6.

The second voltage level conversion unit 230 may include a seventh transistor T7, an eighth transistor T8, a ninth transistor T9, and a tenth transistor T10.

The seventh transistor T7 and the ninth transistor T9 may be connected in series between a high output voltage VH and an intermediate bias voltage Vm for a normal operation. The eighth transistor T8 and the tenth transistor T10 may be connected in series between the high output voltage VH and the intermediate bias voltage Vm.

A gate of the ninth transistor T9 may be connected to a gate of the fifth transistor T5, and a gate of the tenth transistor T10 may be connected with a gate of the sixth transistor T6.

A second voltage conversion signal may be output to the third voltage level conversion unit 240 via a gate of the seventh transistor T7 and a gate of the eighth transistor T8.

The third voltage level conversion unit 240 may include an eleventh transistor T11, a twelfth transistor T12, a thirteenth transistor T13, and a fourteenth transistor T14.

The eleventh transistor T11 and the thirteenth transistor T13 may be connected in series between the high output voltage VH and a low output voltage VL for a normal operation. The twelfth transistor T12 and the fourteenth transistor T14 may be connected in series between the high output voltage VH and the low output voltage VL.

Herein, connection of the eleventh transistor T11 and the thirteenth transistor T13 may be connected with a gate of the fourteenth transistor T14.

A gate of the eleventh transistor T11 may be connected with a gate of the seventh transistor T7, a gate of the twelfth transistor T12 may be connected with a gate of the eighth transistor T8.

A third voltage conversion signal may be output to the output unit 250 via connection of the eleventh transistor T11 and the thirteenth transistor T13.

The output unit 250 may include a fifteenth transistor T15 and a sixteenth transistor T16.

The fifteenth transistor T15 and the sixteenth transistor T16 may be connected in series between the high output voltage VH and the low output voltage VL. Gates of the fifteenth transistor T15 and the sixteenth transistor T16 may be connected to a gate of the thirteenth transistor T13.

Herein, a first output voltage OUT may be output via connection between drains of the fifteenth transistor T15 and the sixteenth transistor T16, and a second output voltage OUTb may be output via connection between gates of the fifteenth transistor T15 and the sixteenth transistor T16.

The operating voltage stabilizer 260 may include a seventeenth transistor T17 and an eighteenth transistor T18. The seventeenth transistor T17 may be connected between the fifth transistor T5 and the intermediate bias voltage Vm, and the eighteenth transistor T18 may be connected between the sixth transistor T6 and the intermediate bias voltage Vm.

As described above, the voltage level converter 200 may have a three-stage positive feedback form formed of the first to third voltage level conversion unit 220 to 240. The operating voltage stabilizer 260 may be placed at the first stage, and may increase a source voltage of intermediate transistors (e.g., NMOS transistors) being fed back to gates. This may enable a normal function to be performed and power consumption to be suppressed although a difference between operating voltages of components in a voltage level converting unit is generated. Herein, the operating voltage stabilizer 260 may be formed of a pair of NMOS transistors, may secure a normal operation although threshold voltages of transistors (e.g., NMOS transistors T5 and T6 and PMOS transistors P3 and P4) are varied.

In the event that the operating voltage stabilizer 260 does not exist, a threshold voltage Vtn of an NMOS transistor may be about 0.4V and a threshold voltage Vtp of a PMOS transistor may be about −0.5V. On the other hand, in the event that the operating voltage stabilizer 260 exists, a threshold voltage Vtp of a PMOS transistor may be about 0.6V and −0.65V, so that influence due to elements is reduced. Also, since NMOS transistors T17 and T18 operate at a saturation region, the operating voltage stabilizer 260 may suppress power consumption. For example, power consumption generated by the voltage level converter 200 under a specific condition may be reduced from several microamperes to several nanoamperes.

An input signal IN of the input unit 210 may have an external CMOS low voltage (e.g., about 0V to 1.0V). The output unit 250 may have an inverter function and be an opposite phase. An output voltage may be a voltage needed for an EEPROM array, for example, about 0V to +2V (VH) or about 0V to −2V (VL).

That is, the high output voltage VH and the low output voltage VL may be randomly adjusted, and the intermediate bias voltage Vm may be decided to have a voltage suitable for minimizing power consumption within a range from 0V to −2V.

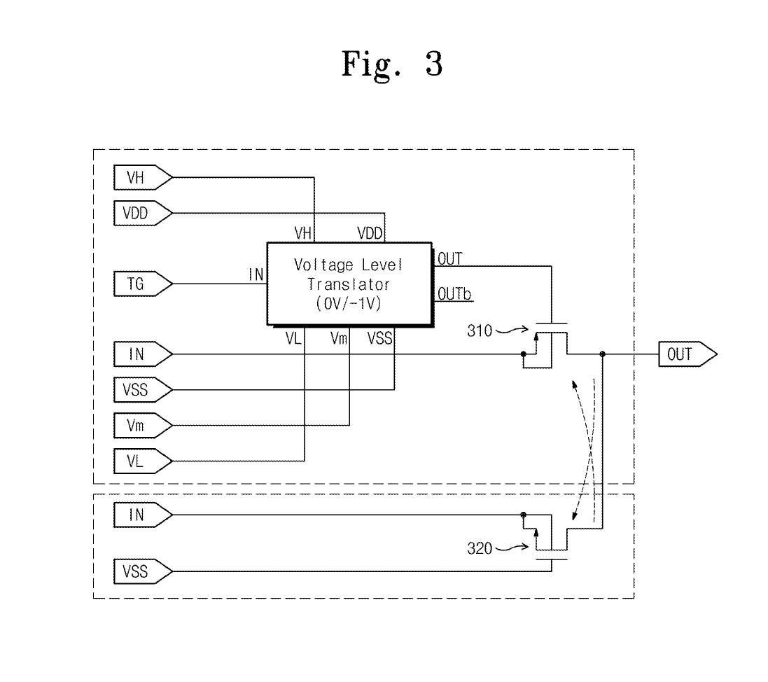

FIG. 3 is a diagram schematically illustrating functional transfer gates according to an embodiment of the inventive concept.

Referring to FIG. 3, functional transfer gates may include a first transfer gate transistor 310 and a second transfer gate transistor 320.

Herein, the first transfer gate transistor 310 may correspond to a first transfer gate 135 (2V/0V/high-impedance (Z)) in FIG. 1, and the second transfer gate transistor 320 may correspond to a second transfer gate 136) (−2V/high-impedance) in FIG. 1.

Outputs of the first transfer gate transistor 310 and the second transfer gate transistor 320 may be connected with a word line.

That is, when an input signal IN has +2V, the first transfer gate transistor 310 may be turned on. In the event that the input signal IN has 0V, the first transfer gate transistor 310 may be turned on when an output of a voltage level converter is −1V, and it may be at a high-impedance state when an output of the voltage level converter is 0V. Herein, the voltage level converter may function as a gate in the interior.

In the event that the input signal IN has 0V, an output of the second transfer gate transistor 320 may be at a high-impedance state.

The first transfer gate transistor 310 and the second transfer gate transistor 320 may not be simultaneously turned on by a front-stage basic CMOS logic circuit (formed of AND gates and NOR gates) and a selective high-impedance output function of the first transfer gate transistor 310 and the second transfer gate transistor 320.

An input signal IN may be applied to wells of the first transfer gate transistor 310 and the second transfer gate transistor 320. Since drains and wells of the first transfer gate transistor 310 and the second transfer gate transistor 320 are reversely biased, a signal may not be transferred between the first transfer gate transistor 310 and the second transfer gate transistor 320. The first transfer gate transistor 310 may be a PMOS transistor, and the second transfer gate transistor 320 may be an NMOS transistor. Since elements of the first transfer gate transistor 310 and the second transfer gate transistor 320 are not turned on, collision may not be generated between the first transfer gate transistor 310 and the second transfer gate transistor 320. Since a voltage corresponding to a multiple of 1 is applied to gate oxide films of the first transfer gate transistor 310 and the second transfer gate transistor 320, a voltage may not be varied.

Since it is divided into bit lines BL1 and BL2 input to a tunneling plate in FIG. 1, it may be separated from an external positive control circuit and an external negative control circuit.

Signals provided into an EEPROM cell may not be collided. The reason may be that the signals are combined in the EEPROM cell.

The EEPROM cell control circuit 100 of the inventive concept may be a circuit which uses symmetric positive and negative voltages (about +2V and −2V) as a high voltage, and the symmetric positive and negative voltages may be matched without collision prior to an input to the EEPROM cell.

Tunneling may be generated at a voltage (e.g., 4V) corresponding to a difference between a positive voltage (e.g., about +2V) and a negative voltage (e.g., about −2V), and a control circuit may be formed of a multiple circuit (about 0V to +2V or about −2V to 0V) being a positive voltage circuit or a negative voltage circuit. Also, a typical CMOS logic circuit of a core may use a positive voltage, which is a low voltage (about 1V0 lower than a voltage corresponding to a multiple of 1. If a voltage of a CMOS gate is lower to be enough to ignore tunneling until a multiple of 1, an EEPROM cell and a peripheral control circuit may be implemented using one type of oxide film (less than about 65 nanometers).

Also, as a 65 nm or less CMOS input/output cell is used, an EEPROM cell control circuit may be implemented by one type of gate oxide film using a process compatible with CMOS.

While the inventive concept has been described with reference to exemplary embodiments, it will be apparent to those skilled in the art that various changes and modifications may be made without departing from the spirit and scope of the present invention. Therefore, it should be understood that the above embodiments are not limiting, but illustrative.

What is claimed is:

1. An EEPROM cell control circuit, comprising:
a signal input circuit configured to receive control signals for controlling an EEPROM cell from an external device;
a bit line control circuit configured to provide a positive voltage and a negative voltage to two bit lines connected with the EEPROM cell in response to the control signals; and
a word line control circuit configured to control a sense gate line in response to the control signals at a sense operation and to apply a positive voltage and a negative voltage to a word line.

2. The EEPROM cell control circuit of claim 1, wherein the input circuit comprises:
a first inverter configured to select either program and erase operations or standby and read operations;
a second inverter configured to receive a program/erase mode control signal for controlling a program mode and an erase mode; and
a third inverter configured to receive a word line selection signal for word line selection.

3. The EEPROM cell control circuit of claim 1, wherein the bit line control circuit comprises:
a first AND gate configured to receive control signals for applying a negative voltage to a first bit line of the two bit lines;
a first voltage level converter connected with the first AND gate and to apply a negative voltage to the first bit line;
a first NAND gate configured to receive control signals for applying a positive voltage to a second bit line of the two bit lines; and
a second voltage level converter connected with the first NAND gate and to apply a positive voltage to the second bit line.

4. The EEPROM cell control circuit of claim 3, wherein each of the first and second voltage level converters comprises:
an input unit configured to receive a signal;
voltage level conversion units connected to have a three-stage structure and to convert a voltage of the input signal based on a power supply voltage, a ground voltage, a high output voltage, a low output voltage, and an intermediate voltage;
an output unit configured to output a signal the voltage of which is converted by the voltage level conversion units; and
an operating voltage stabilizer configured to secure a normal function operation although a difference between operating voltages of elements in a voltage level conversion unit, located at a first stage, from among the voltage level conversion units is generated and to suppress power consumption.

5. The EEPROM cell control circuit of claim 4, wherein the operating voltage stabilizer includes two NMOS transistors connected with the intermediate voltage.

6. The EEPROM cell control circuit of claim 1, wherein the word line control circuit comprises:
a second NAND gate configured to receive a word line selection signal and a control signal for applying different voltages to two sense gate lines of the EEPROM cell at a read operation; and
a first inverter circuit connected with the second NAND gate and configured to apply an operating voltage for the read operation to the two sense gate lines of the EEPROM cell.

7. The EEPROM cell control circuit of claim 1, wherein the word line control circuit comprises:
a second inverter circuit configured to receive a word line selection signal and a control signal for generating a voltage applied to a read voltage line at a read operation and to apply a read voltage to the read voltage line.

8. The EEPROM cell control circuit of claim 1, further comprising:
a CMOS logic circuit configured to receive a word line selection signal and a control signal for generation of a positive voltage and a negative voltage applied to the word line;
a third voltage level converter connected with the CMOS logic circuit and to generate a positive voltage applied to the word line;
a first transfer gate configured to transfer an output of the third voltage level converter to the word line;
a fourth voltage level converter connected with the CMOS logic circuit and to generate a negative voltage applied to the word line; and
a second transfer gate configured to transfer an output of the fourth voltage level converter to the word line.

9. The EEPROM cell control circuit of claim 8, wherein a bias condition between drains and wells of the first and second transfer gates are at a reverse bias state such that a signal is not transferred between the first and second transfer gates.

10. The EEPROM cell control circuit of claim 9, wherein the first transfer gate generates a positive voltage, a zero voltage, and high-impedance, and the second transfer gate generates a negative voltage and high-impedance.

11. The EEPROM cell control circuit of claim 8, wherein the CMOS logic circuit comprises:
second and third NAND gates configured to receive a word line selection signal and a control signal for generation of a positive voltage of the third voltage level converter;
a first NOR gate configured to perform a NOR operation on outputs of the second and third NAND gates to output a result of the NOR operation to the third voltage level converter;
fourth and fifth NAND gates configured to receive a word line selection signal and a control signal for generation of a negative voltage of the fourth voltage level converter; and
a second NOR gate configured to perform a NOR operation on outputs of the fourth and fifth NAND gates to output a result of the NOR operation to the fourth voltage level converter.

12. The EEPROM cell control circuit of claim 8, wherein each of the third and fourth voltage level converters comprises:
an input unit configured to receive a signal;
voltage level conversion units connected to have a three-stage structure and to convert a voltage of the input signal based on a power supply voltage, a ground voltage, a high output voltage, a low output voltage, and an intermediate voltage;
an output unit configured to output a signal the voltage of which is converted by the voltage level conversion units; and
an operating voltage stabilizer configured to secure a normal function operation although a difference between operating voltages of elements in a voltage level conversion unit, located at a first stage, from among the voltage level conversion units is generated and to suppress power consumption.

13. The EEPROM cell control circuit of claim 12, wherein the operating voltage stabilizer includes two NMOS transistors connected with the intermediate voltage.
